(19) United States
(12) Patent Application Publication
(10) Pub. No.: US 2017/0365664 A1
(43) Pub. Date: Dec. 21, 2017

(54) SEMICONDUCTOR DEVICE, INVERTER CIRCUIT, DRIVING DEVICE, VEHICLE, AND ELEVATOR

(71) Applicant: Kabushiki Kaisha Toshiba, Minato-ku (JP)

(72) Inventors: Ryosuke IIJIMA, Setagaya (JP); Tatsuo SHIMIZU, Shinagawa (JP); Chiharu OTA, Kawasaki (JP)

(73) Assignee: Kabushiki Kaisha Toshiba, Minato-ku (JP)

(21) Appl. No.: 15/440,389

(22) Filed: Feb. 23, 2017

(30) Foreign Application Priority Data
Jun. 15, 2016 (JP) 2016-118566

(51) Int. Cl. H01L 29/16; H01L 29/739; H01L 29/51

(52) U.S. Cl. CPC H01L 29/1608; H01L 29/512; H01L 29/7393

(57) ABSTRACT

A semiconductor device according to an embodiment, includes: a silicon carbide layer; a gate electrode; and a gate insulating layer, the gate electrode including a p-type silicon carbide region containing aluminum, the gate insulating layer having a first region and a second region, the first region including a silicon oxide or a silicon oxynitride, the second region being positioned between the first region and the gate electrode, the second region including an oxide containing aluminum.

### CROSS-REFERENCE TO RELATED APPLICATION

This application is based upon and claims the benefit of priority from Japanese Patent Applications No. 2016-118566, filed on Jun. 15, 2016, the entire contents of which are incorporated herein by reference.

### FIELD

Embodiments described herein relate generally to a semiconductor device, an inverter circuit, a driving device, a vehicle, and an elevator.

### BACKGROUND

Silicon carbide (SiC) has attracted attention as a material for a next generation semiconductor device. Silicon carbide has excellent properties including a band gap three times than that of silicon (Si), breakdown field strength approximately ten times than that of Si, and thermal conductivity approximately three times larger than that of Si. Using the properties can achieve a semiconductor device capable of operating at a high temperature with a low loss.

The achievement of a high threshold voltage is desired in order to reduce a leakage current in an off state or prevent its malfunction of a transistor including silicon carbide. An exemplary method of achieving the high threshold voltage is to make an impurity in a channel region high. However, when the impurity in the channel region has a high concentration, a problem that channel mobility decreases and on-resistance increases occurs.

### BRIEF DESCRIPTION OF THE DRAWINGS

FIG. 1 is a schematic cross-sectional view of a semiconductor device according to a first embodiment;

FIG. 2 is a schematic cross-sectional view of the semiconductor device being manufactured by a semiconductor device manufacturing method according to the first embodiment;

FIG. 3 is a schematic cross-sectional view of the semiconductor device being manufactured by a semiconductor device manufacturing method according to the first embodiment;

FIG. 4 is a schematic cross-sectional view of the semiconductor device being manufactured by the semiconductor device manufacturing method according to the first embodiment;

FIG. 5 is a schematic cross-sectional view of the semiconductor device being manufactured by the semiconductor device manufacturing method according to the first embodiment;

FIG. 6 is a schematic cross-sectional view of the semiconductor device being manufactured by the semiconductor device manufacturing method according to the first embodiment;

FIG. 7 is a schematic cross-sectional view of the semiconductor device being manufactured by the semiconductor device manufacturing method according to the first embodiment;

FIG. 8 is a schematic cross-sectional view of the semiconductor device being manufactured by the semiconductor device manufacturing method according to the first embodiment;

FIG. 9 is a view for describing a function and an effect of the semiconductor device according to the first embodiment;

FIGS. 10A and 10B are views for describing a function and an effect of the semiconductor device according to the first embodiment;

FIG. 11 is a view for describing a function and an effect of the semiconductor device according to the first embodiment;

FIG. 12 is a view for describing a function and an effect of a semiconductor device according to a third embodiment;

FIG. 13 is a schematic cross-sectional view of a semiconductor device according to a fourth embodiment;

FIGS. 14A and 14B are views for describing a function and an effect of the semiconductor device according to the fourth embodiment;

FIG. 15 is a schematic cross-sectional view of a semiconductor device according to a fifth embodiment;

FIG. 16 is a schematic cross-sectional view of a semiconductor device according to a sixth embodiment;

FIG. 17 is a schematic view of a driving device according to a seventh embodiment;

FIG. 18 is a schematic view of a vehicle according to an eighth embodiment;

FIG. 19 is a schematic view of a vehicle according to a ninth embodiment; and

FIG. 20 is a schematic view of an elevator according to a tenth embodiment.

### DETAILED DESCRIPTION

Embodiments of the present disclosure will be described below with reference to the drawings. Note that, in the following descriptions, for example, the same members or similar members are denoted with the same reference signs. The descriptions of members, for example, that have been given once, will be appropriately omitted.

In the following descriptions, representations of n⁺, n, n⁻, and p⁺, p, p⁻ give relative high and low levels of impurity concentration in each conductive type. That is, n⁺ represents n-type impurity concentration relatively higher than that of n. n⁻ represents n-type impurity concentration relatively lower than that of n. p⁺ represents p-type impurity concentration relatively higher than that of p. p⁻ represents p-type impurity concentration relatively lower than that of p. Note that, in some cases, an n⁺-type and an n⁻-type may be simply expressed by an n-type. A p⁺-type and a p⁻-type may be simply expressed by a p-type.

### First Embodiment

A semiconductor device according to the present embodiment, includes: a silicon carbide layer; a gate electrode; and a gate insulating layer, the gate electrode including a p-type silicon carbide region containing aluminum, the gate insulating layer having a first region and a second region, the first region including a silicon oxide or a silicon oxynitride, the second region being positioned between the first region and the gate electrode, the second region including an oxide containing aluminum.

The semiconductor device according to the present embodiment can achieve a high threshold voltage without reducing channel mobility, due to a function of the p-type SiC gate electrode and a dipole in the gate insulating layer.

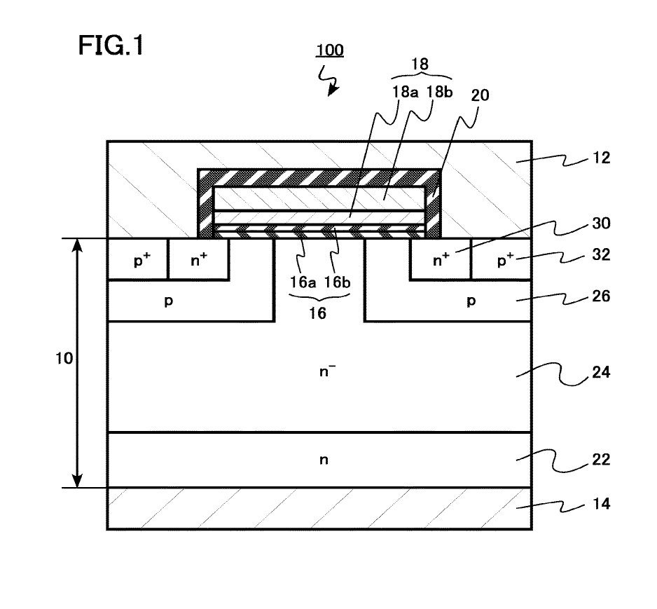

FIG. 1 is a schematic cross-sectional view of the semiconductor device according to the present embodiment. The metal oxide semiconductor field effect transistor (MOSFET) 100 is, for example, a double implantation MOSFET (DIMOSFET) including a well region and a source region formed by ion implantation. The MOSFET 100 is an n-type MOSFET in which an electron serves as a carrier.

The MOSFET 100 includes the SiC layer (the silicon carbide layer) 10, a source electrode 12, a drain electrode 14, the gate insulating layer 16, the gate electrode 18, and an interlayer insulating film 20. The SiC layer 10 includes a drain region (an SiC substrate) 22, a drift region 24, a well region 26, a source region 30, a well contact region 32.

The SiC layer 10 is, for example, a single crystal of 4H-SiC.

SiC can have a plurality of crystal forms. Examples of the crystal forms include a hexagonal crystal system 4H-SiC, a hexagonal crystal system 6H-SiC, and a cubic crystal system 3C-SiC. The crystal form of the SiC can be identified, for example, by observing the configuration of atoms with a transmission electron microscope (TEM). The crystal form of the SiC can be identified, for example, by X-ray diffraction (XRD).

The SiC layer 10 has a first plane and a second plane. In FIG. 1, the first plane is a plane on the upper side of the figure. The second plane is a plane on the lower side of the figure. The first plane and the second plane are also referred to as a front face and a back face, respectively, below.

A case where the first plane slants at an angle of 0 to 8 degrees to a (0001) face and the second plane slants at an angle of 0 to 8 degrees to a (000-1) face, will be exemplarily described. The (0001) face is referred to as a silicon face. The (000-1) face is referred to as a carbon face.

The drain region 22 is n-type SiC. The drain region 22 includes, for example, nitrogen (N) as an n-type impurity. The concentration of the n-type impurity in the drain region 22 is, for example, between 1×10¹⁸ and 1×10²¹ cm⁻³ inclusive.

In order to reduce contact resistance between the drain electrode 14 and the drain region 22, the concentration of the n-type impurity in the second plane of the drain region 22 is preferably 1×10¹⁹ cm⁻³ or more, and more preferably, 1×10²⁰ cm⁻³ or more.

The drift region 24 is provided on the drain region 22. The drift region 24 is, for example, n⁻-type SiC formed on the drain region 22 by epitaxial growth. The thickness of the drift region 24 is, for example, between 5 μm and 150 μm inclusive.

The drift region 24 includes, for example, nitrogen (N) as an n-type impurity. The concentration of the n-type impurity in the drift region 24 is, for example, between 5×10¹⁵ cm⁻³ and 2×10¹⁶ cm⁻³ inclusive.

The well region 26 is provided on the drift region 24. The well region 26 is p-type SiC. The well region 26 is provided between the source region 30 and the drift region 24. The well region 26 functions as a channel region of the MOSFET 100.

The well region 26 includes, for example, aluminum (Al) as a p-type impurity. The concentration of the p-type impurity in the well region 26 is, for example, between 5×10¹⁵ and 1×10¹⁸ cm⁻³ inclusive. In terms of inhibition of the reduction of the channel mobility of the MOSFET 100, the concentration of the p-type impurity is preferably 5×10¹⁷ cm⁻³ or less, more preferably, 1×10¹⁷ cm⁻³ or less.

The depth of the well region 26 is, for example, between 0.4 μm and 0.8 μm inclusive.

The source region 30 is provided in the well region 26. The source region 30 is n⁺-type SiC. The source region 30 includes, for example, nitrogen (N) as an n-type impurity. The concentration of the n-type impurity in the source region 30 is, for example, between 1×10¹⁸ cm⁻³ and 1×10²¹ cm⁻³ inclusive.

In terms of reduction of contact resistance between the source electrode 12 and the source region 30, the concentration of the n-type impurity in the first plane of the source region 30 is preferably 1×10¹⁹ cm⁻³ or more, more preferably, 1×10²⁰ cm⁻³ or more.

The depth of the source region 30 is shallower than the depth of the well region 26, and is, for example, between 0.2 μm and 0.4 μm inclusive.

The well contact region 32 is provided in the well region 26. The well contact region 32 is provided in a lateral direction of the source region 30.

The well contact region 32 is p⁺-type SiC. The well contact region 32 includes, for example, aluminum (Al) as a p-type impurity. The concentration of the p-type impurity in the well contact region 32 is, for example, between 1×10¹⁸ cm⁻³ and 1×10²¹ cm⁻³ inclusive.

The depth of the well contact region 32 is shallower than the depth of the well region 26, and is, for example, between 0.2 μm and 0.4 μm inclusive.

The gate insulating layer 16 is provided between the SiC layer 10 and the gate electrode 18. The gate insulating layer 16 is formed on the source region 30, the well region 26, and the drift region 24. The gate insulating layer 16 is provided between the source region 30, the well region 26, the drift region 24, and the gate electrode 18.

The thickness of the gate insulating layer 16 is, for example, between 50 nm and 100 nm inclusive.

The gate insulating layer 16 has the first region 16a and the second region 16b. The first region 16a is provided on the SiC layer 10 in contact with the SiC layer 10. The second region 16b is provided between the first region 16a and the gate electrode 18. The second region 16b is in contact with the gate electrode 18.

The first region 16a includes the silicon oxide or the silicon oxynitride. The second region 16b includes the aluminum oxide. A case where the first region 16a is a silicon oxide film and the second region 16b is an aluminum oxide film, will be exemplarily described.

When the second region 16b is the aluminum oxide film, the number of aluminum atoms to the sum of the number of the aluminum atoms and the number of silicon atoms (Al/(Al+Si)) in the second region 16b, is 1. When the first region 16a is the silicon oxide film, the number of aluminum atoms to the sum of the number of the aluminum atoms and the number of silicon atoms (Al/(Al+Si)) in the first region 16a, is O.

The gate electrode 18 is provided on the gate insulating layer 16. The gate electrode 18 includes a p-type silicon carbide region 18a and an n-type or a p-type silicon region 18b. The silicon carbide region 18a is interposed between the gate insulating layer 16 and the silicon region 18b.

The silicon carbide region 18a is p-type 4H-SiC containing aluminum as a p-type impurity. The silicon carbide region 18a is polycrystalline 4H-SiC. The thickness of the silicon carbide region 18a is, for example, between 10 nm and 30 nm inclusive.

In terms of metallization of the 4H-SiC in the silicon carbide region 18a, the concentration of the aluminum in the silicon carbide region 18a is preferably 1×10¹⁹ cm⁻³ or more, more preferably, 1×10²⁰ cm⁻³ or more. The concentration is further preferably 1×10²¹ cm⁻³.

The silicon region 18b includes an n-type impurity or a p-type impurity. The silicon region 18b is, for example, n-type or p-type polycrystalline silicon. The n-type impurity is, for example, phosphorus (P) or arsenic (As). The p-type impurity is, for example, boron (B).

The thickness of the silicon region 18b is thicker than the thickness of the silicon carbide region 18a. The thickness of the silicon region 18b is, for example, between 100 nm and 500 nm inclusive.

In terms of metallization of the silicon in the silicon region 18b, the concentration of the n-type impurity or the p-type impurity in the silicon region 18b is preferably 1×10¹⁹ cm³ or more, more preferably, 1×10²⁰ cm⁻³ or more. The concentration is further preferably 1×10²¹ cm⁻³.

The interlayer insulating film 20 is provided on the gate electrode 18. The interlayer insulating film 20 is, for example, a silicon oxide film.

The well region 26 interposed between the source region 30 and the drift region 24 below the gate electrode 18, functions as the channel region of the MOSFET 100.

The source electrode 12 is provided on the front face of the SiC layer 10. The source electrode 12 is electrically connected to the source region 30 and the well contact region 32. The source electrode 12 is in contact with the well contact region 32 and the source region 30. The source electrode 12 also has a function of applying potential to the well region 26.

The source electrode 12 is metal. The metal that forms the source electrode 12 has, for example, a stacked structure of titanium (Ti) and aluminum (Al). The metal that forms the source electrode 12 may react with the SiC layer 10 so as to form metal silicide or metal carbide.

The drain electrode 14 is provided on the back face of the SiC layer 10. The drain electrode 14 is electrically connected to the drain region 22.

The drain electrode 14 is metal. The metal that forms the drain electrode 14 is, for example, nickel silicide.

Note that, the types and the concentrations of elements contained in the SiC layer 10, the gate insulating layer 16, and the gate electrode 18, can be measured by secondary ion mass spectrometry (SIMS).

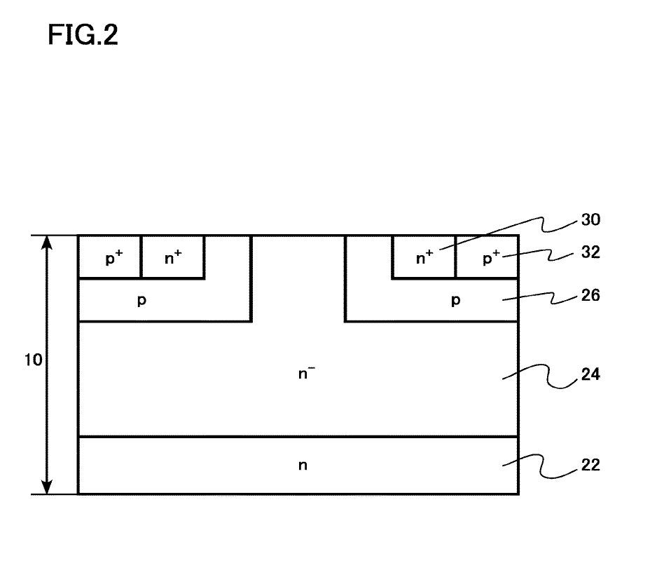

Next, a method of manufacturing the semiconductor device according to the present embodiment, will be described. FIGS. 2 to 8 are schematic cross-sectional views of the semiconductor device being manufactured in the method of manufacturing the semiconductor device according to the present embodiment.

First, an n-type SiC substrate having the first plane being a silicon face and the second plane being a carbon face is prepared. The SiC substrate is to be the drain region 22. The n-type SiC substrate is the 4H-SiC.

Next, the n⁻-type drift region 24 is formed on the first plane of the n-type SiC substrate by the epitaxial growth. The SiC substrate and the n⁻-type drift region 24 are included in the SiC layer 10.

Next, ion implantation of aluminum (Al) being a p-type impurity is selectively performed to the drift region 24 by photolithography and an ion implantation method. The ion implantation forms the well region 26.

Next, ion implantation of aluminum (Al) being a p-type impurity is selectively performed to the well region 26 by photolithography and an ion implantation method. The ion implantation forms the well contact region 32.

Next, ion implantation of nitrogen (N) being an n-type impurity is selectively performed to the well region 26 by photolithography and an ion implantation method. The ion implantation forms the source region 30 (refer to FIG. 2).

Next, annealing for activating the p-type impurities and the n-type impurity, is performed. The activation annealing is performed, for example, at a temperature of between 1700° C. and 1900° C. inclusive in an inert gas atmosphere.

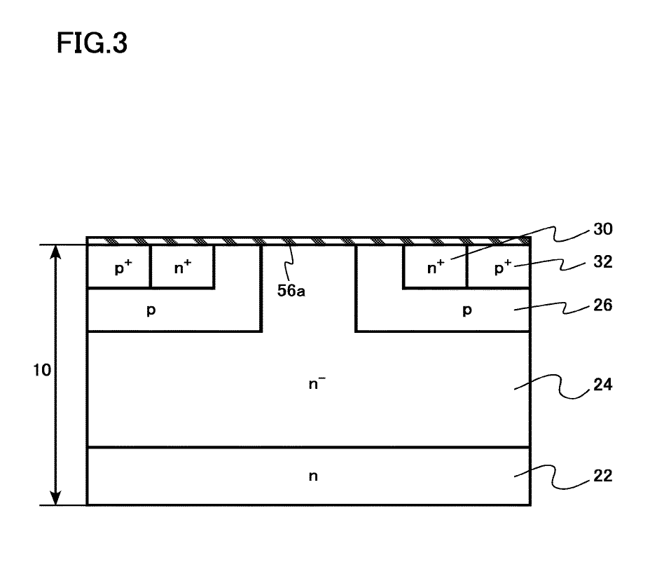

Next, a silicon oxide film 56a is formed on the front face of the SiC layer 10 (refer to FIG. 3). The silicon oxide film 56a is formed by, for example, a chemical vapor deposition (CVD) method.

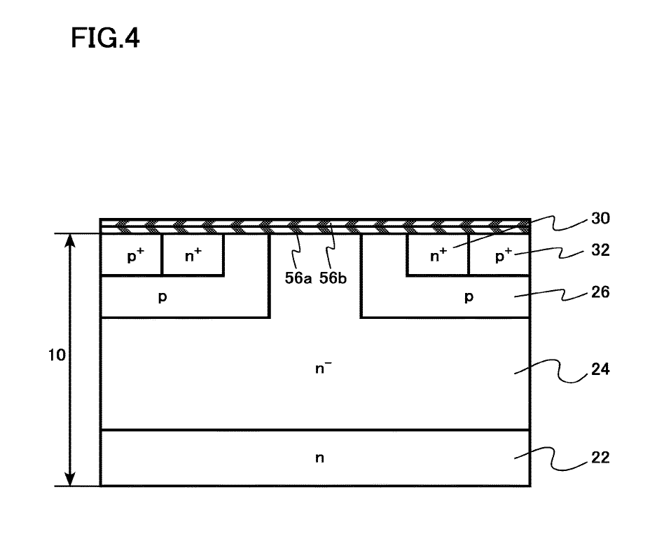

Next, an aluminum oxide film 56b is formed on the silicon oxide film 56a (refer to FIG. 4). The aluminum oxide film 56b is formed by, for example, a CVD method, an atomic layer deposition (ALD) method, or a sputtering method.

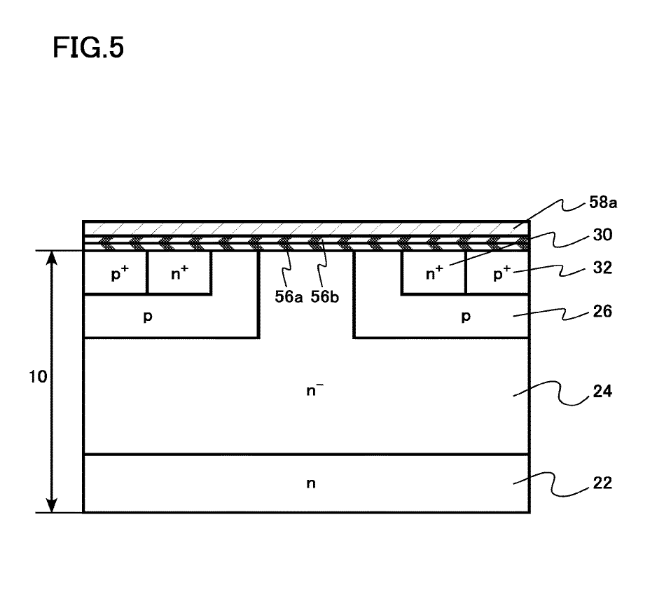

Next, a polycrystalline SiC film 58a is formed on the aluminum oxide film 56b (refer to FIG. 5). The SiC film 58a is formed by, for example, a CVD method or a sputtering method.

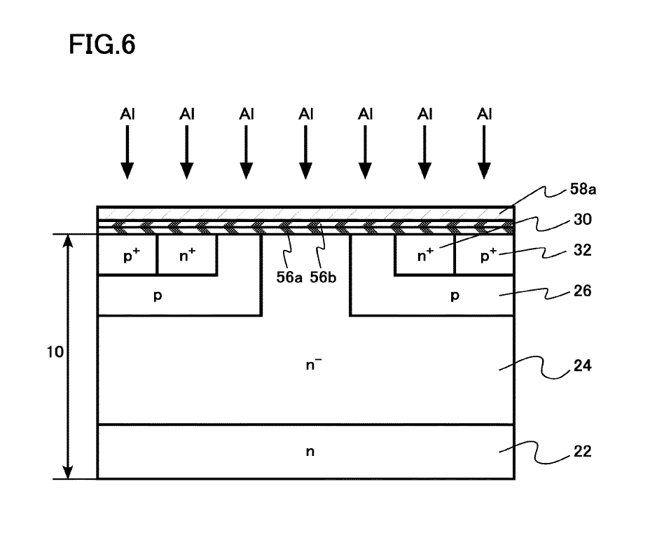

Next, ion implantation of aluminum is performed to the SiC film 58a (refer to FIG. 6). After that, activation annealing for the aluminum is performed. The activation annealing is performed, for example, at a temperature of between 1600° C. and 1900° C. inclusive in an inlet gas atmosphere.

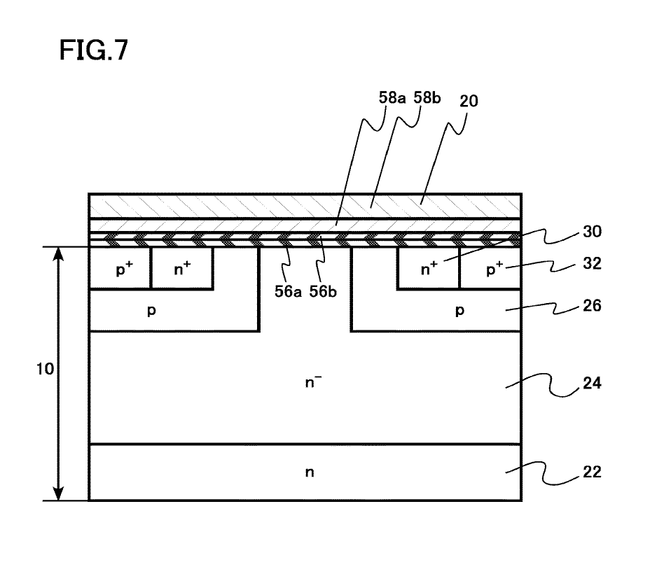

Next, an n-type or a p-type silicon film 58b is formed on the SiC film 58a (refer to FIG. 7). The silicon film 58b is formed by, for example, a CVD method.

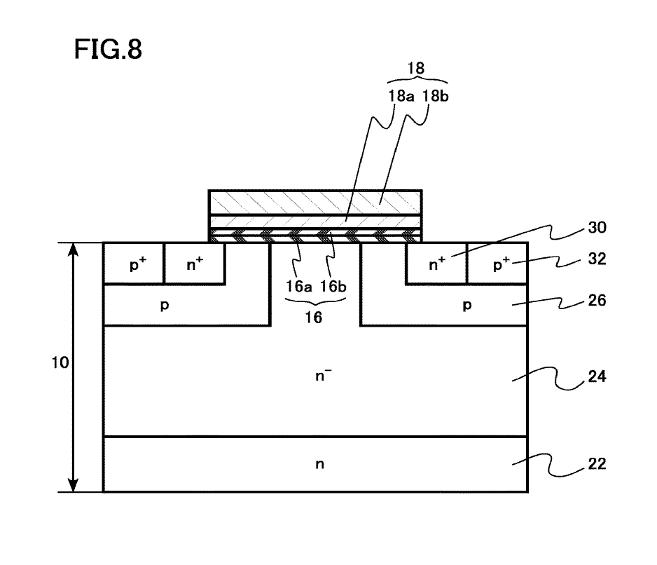

Next, patterning is performed to the silicon film 58b, the SiC film 58a, the aluminum oxide film 56b, and the silicon oxide film 56a (refer to FIG. 8). For example, photolithography and dry etching perform the patterning to the silicon film 58b, the SiC film 58a, the aluminum oxide film 56b, and the silicon oxide film 56a.

The silicon film 58b and the SiC film 58a to which the patterning has been performed, are to be the silicon region 18b and the silicon carbide region 18a included in the gate electrode 18, respectively. The aluminum oxide film 56b and the silicon oxide film 56a to which the patterning has been performed, are to be the second region 16b and the first region 16a included in the gate insulating layer 16, respectively.

Next, the interlayer insulating film 20 is formed on the SiC layer 10 and on the gate electrode 18. For example, patterning is performed so as to form the interlayer insulating film 20 after a silicon oxide film is deposited by a CVD method.

Next, the source electrode 12 is formed on the source region 30 and the well contact region 32. The source electrode 12 is formed by, for example, sputtering with titanium and aluminum.

Next, the drain electrode 14 is formed on the back face of the SiC layer 10. The drain electrode 14 is, for example, the nickel silicide, and is formed by sputtering with nickel and heat treatment.

The MOSFET 100 illustrated in FIG. 1 is formed by the above manufacturing method.

A function and an effect of the semiconductor device according to the present embodiment will be described below.

Inhibiting a leakage current in an off state of a MOSFET is required in terms of achievement of low power consumption. Preventing the MOSFET from being turned on due to malfunction is required in terms of stabilization of the operation of the MOSFET. It is preferable that the threshold voltage of the MOSFET is increased in order to inhibit the leakage current in the off state and prevent the malfunction.

It is thought that making the energy level of an upper end of the valence band of a semiconductor in a p-type channel region and the work function of a gate electrode close to each other in order to increase the threshold voltage of the n-type MOSFET. In the off state of the MOSFET, the energy band of the semiconductor bends so that the Fermi level of the p-type channel region and the work function of the gate electrode correspond to each other. The Fermi level of the p-type channel region is positioned near the upper end of the valence band of the semiconductor of the p-type channel region.

Accordingly, by making the energy level of the upper end of the valence band of the semiconductor of the p-type channel region and the work function of the gate electrode close to each other, the bend of the energy band of the semiconductor in the off state of the MOSFET is inhibited. Therefore, the threshold voltage of the MOSFET increases.

When the work function of the gate electrode is larger than the energy level of the upper end of the valence band of the semiconductor of the p-type channel region, the threshold voltage of the MOSFET further increases.

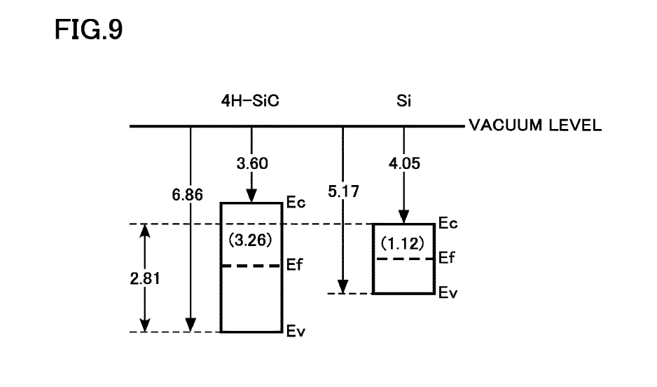

FIG. 9 is a view for describing a function and an effect of the semiconductor device according to the present embodiment. FIG. 9 illustrates a calculation result of semiconductor energy band structures by a first principles calculation.

FIG. 9 is a view of the energy band structures of silicon (Si) and 4H-SiC. The energy difference between the vacuum level (the energy level in a vacuum) and an lower end of the conduction band (Ec in the figure), the energy difference between the vacuum level and an upper end of the valence band (Ev in the figure), the band gap energy, of each of the materials, are illustrated. In the figure, a numerical value in brackets for each of the materials indicates the band gap energy.

For example, the energy difference between the vacuum level and the lower end of the conduction band (Ec) of the silicon is 4.05 eV. The energy difference between the vacuum level and the upper end of the valence band (Ev) of the silicon is 5.17 eV.

For example, the energy difference between the vacuum level and the lower end of the conduction band (Ec) of the 4H-SiC is 3.60 eV. The energy difference between the vacuum level and the upper end of the valence band (Ev) of the 4H-SiC is 6.86 eV.

Note that, a work function is the energy difference between a vacuum level and the Fermi level of a substance being an object (e.g., the Fermi level is denoted with Ef in the figure). In FIG. 9, a case where the Fermi level is positioned at the center of each band gap, is exemplified.

When an n-type impurity is introduced into a semiconductor so as to be metalized, the Fermi level of the semiconductor is considered to correspond to a lower end of the conduction band (Ec). Accordingly, the work function of the semiconductor is considered to correspond to the energy level of the lower end of the conduction band (Ec). When a p-type impurity is introduced into the semiconductor so as to be metalized, the Fermi level of the semiconductor is considered to correspond to the energy level of an upper end of the valence band (Ev). Accordingly, the work function of the semiconductor can be considered to correspond to the energy difference between the vacuum level and the upper end of the valence band (Ev).

For example, if the p-type channel region is the 4H-SiC, using p-type silicon for the gate electrode increases the threshold voltage of the MOSFET higher than using n-type silicon for the gate electrode. As illustrated in FIG. 9, this is because the energy level of the upper end of the valence band (Ev) of the semiconductor of the 4H-SIC (6.86 eV) is closer to the work function of the p-type silicon (the energy difference between the vacuum level and the upper end of the valence band=5.17 eV) in comparison to the work function of the n-type silicon (the energy difference between the vacuum level and the lower end of the conduction band=4.05 eV). The threshold voltage can be increased by 1.12 V, which corresponds to the band gap energy of the silicon, in comparison to the use of the n-type silicon for the gate electrode.

When the p-type channel region is the 4H-SiC, p-type 4H-SiC is applied for the gate electrode so that the threshold voltage can further increase. This is because the work function of the p-type 4H-SiC corresponds to the energy level of the upper end of the valence band (Ev) of the semiconductor of the 4H-SiC. The threshold voltage can be increased by 2.81 V in comparison to the use of the n-type silicon for the gate electrode.

The MOSFET 100 has the p-type silicon carbide region 18a in the gate electrode 18. The silicon carbide region 18a is the 4H-SiC containing the aluminum as the p-type impurity.

Therefore, in the MOSFET 100, the threshold voltage can be increased by 2.81 V in comparison to the use of the n-type silicon for the gate electrode.

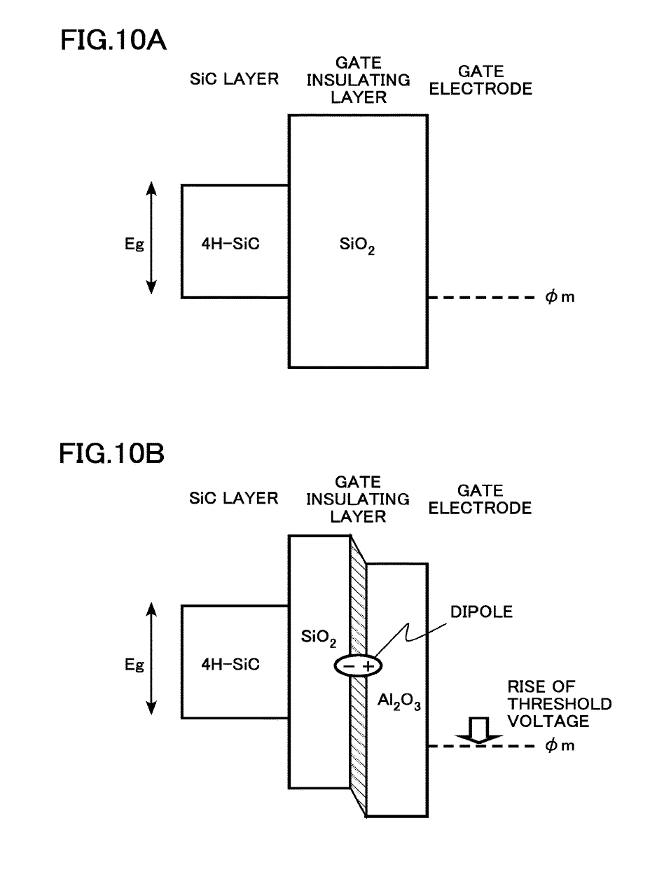

FIGS. 10A to 10B are views each for describing a function and an effect of the semiconductor device according to the present embodiment. FIGS. 10A and 10B are views each illustrating the bands of an SiC layer, agate insulating layer, and a gate electrode.

FIG. 10A illustrates a case where the gate insulating layer is a single film including a silicon oxide (SiO₂ in the figure) film. FIG. 10B illustrates a case where the gate insulating layer is a stacked film of a silicon oxide film and an aluminum oxide (Al₂O₃ in the figure) film, similarly to the present embodiment.

As illustrated in FIG. 10B, when the silicon oxide film and the aluminum oxide film are in contact with each other, a dipole is formed therebetween. The dipole that has been formed has a negative charge on the side of the silicon oxide film and a positive charge on the side of the aluminum oxide film.

As illustrated in FIG. 10B, due to the function of the dipole that has been formed, the work function of the gate electrode (φm in the figure) apparently increases larger than that in the case where the gate insulating layer is the single film including the silicon oxide film. Specifically, the work function increases by approximately 1.2 V. Accordingly, the threshold voltage of the MOSFET 100 increases in a quantity of approximately 1.2 V.

The MOSFET 100 can achieve a high threshold voltage due to the p-type SiC gate electrode and the function of the dipole in the gate insulating layer. For example, the threshold voltage increases by approximately 4.01 V (=2.81 V+1.2 V) higher than a case where the gate insulating layer is the single film including the silicon oxide film and the gate electrode includes the n-type silicon.

Therefore, the high threshold voltage can be achieved without an impurity having a high concentration, introduced to the channel region. Thus, the high threshold voltage can be achieved without the channel mobility reduced.

The thickness of the silicon carbide region 18a preferably has a predetermined thickness in terms of the achievement of the high threshold voltage. Thus, the thickness of the silicon carbide region 18a is preferably 20 nm or more.

The gate electrode 18 of the MOSFET 100 includes the p-type silicon carbide region 18a and the n-type or the p-type silicon region 18b. Typically, the impurity activation rate of silicon carbide is lower than that of silicon. Therefore, silicon can be made to have low resistance with respect to silicon carbide.

The MOSFET 100 includes the n-type or the p-type silicon region 18b having resistance lower than that of the p-type silicon carbide region 18a so that a wiring delay resulting from the gate electrode 18 can be inhibited. Therefore, the MOSFET 100 can be accelerated.

Particularly, the thickness of the silicon region 18b is made thicker than the thickness of the silicon carbide region 18a so that the gate electrode 18 has a structure further suitable to the low resistance.

Next, a function and an effect relating to the method of manufacturing the MOSFET 100, will be described.

The p-type silicon carbide region 18a of the MOSFET 100 is formed by performing the ion implantation of the aluminum to the SiC film 58a.

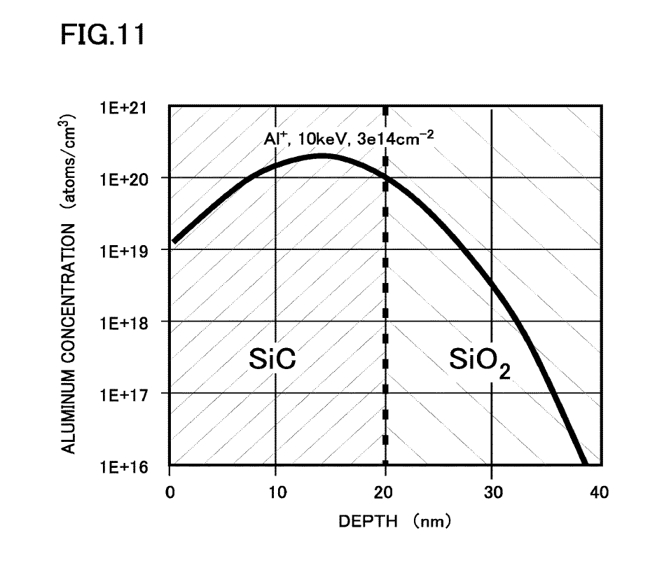

FIG. 11 is a graphical representation for describing a function and an effect of the semiconductor device according to the present embodiment. FIG. 11 illustrates a profile of the concentration of aluminum in films when ion implantation of an aluminum ion under conditions of 10 keV and 3e14 cm⁻² is performed to an SiO₂ film and an SiC film. The ion implantation is performed from a surface of the SiC film. The thickness of the SiC film is 20 nm.

As illustrated in FIG. 11, it can be seen that the aluminum penetrates to the side of the SiO₂ film due to the ion implantation. When a gate insulating layer is formed of a single film including a silicon oxide film, there is a risk that aluminum distributed in the silicon oxide film becomes a fluctuation factor of the property of the gate insulating layer. For example, there is a risk that the breakdown voltage, the leak property, and the permittivity of the gate insulating layer vary.

It is difficult to control the penetrating amount of the aluminum. Accordingly, there is a risk that the variation of the penetrating amount of the aluminum becomes a fluctuation factor of varying the property of a MOSFET.

The MOSFET 100 according to the present embodiment has the gate insulating layer 16 including a stacked film of the silicon oxide film and the aluminum oxide film. The aluminum oxide film is provided on the side in contact with the gate electrode 18.

Accordingly, when the aluminum penetrates, the quantity of the aluminum that has penetrated remains at less than 1% of the aluminum originally present in the film so as not to contribute to the variation of the property of the gate insulating layer 16. Therefore, the MOSFET 100 can inhibit the variation of the property in manufacturing.

The MOSFET 100 includes the silicon carbide region 18a having a thickness thinner than the thickness of the silicon region 18b so that the gate electrode 18 is easily processed. This is because silicon carbide typically has etching tolerance higher than that of silicon.

Note that, even when the first region 16a of the gate insulating layer 16 is a silicon oxynitride film instead of the silicon oxide film, a similar function and a similar effect are acquired.

According to the present embodiment, the MOSFET 100 having a high threshold voltage is achieved. The MOSFET 100 having a high speed is achieved. The MOSFET 100 having a small variation of property fluctuations is achieved. The MOSFET 100 that is easily processed in the manufacturing, is achieved.

### Second Embodiment

The present embodiment is different from the first embodiment in that a second region contains silicon and the number of aluminum atoms to the sum of the number of the aluminum atoms and the number of silicon atoms is 0.08 or more and less than 1. Therefore, the descriptions of duplicate details with respect to the first embodiment, will be omitted.

A gate insulating layer 16 of a MOSFET according to the present embodiment has a first region 16a and the second region 16b, similarly to the first embodiment.

The first region 16a is a silicon oxide film, and the second region 16b is a compound of an aluminum oxide film and a silicon oxide film, or a mixture of the aluminum oxide and the silicon oxide film. The number of the aluminum atoms to the sum of the number of the aluminum atoms and the number of the silicon atoms (hereinafter, also referred to as Al/(Al+Si)) in the second region 16b is 0.08 or more and less than 1.

Note that, the value of the Al/(Al+Si) in the second region 16b can be acquired by calculation, based on concentration measurement results of the aluminum and the silicon due to SIMS.

The second region 16b is formed by, for example, a sputtering method with a target of aluminum oxide and a target of silicon oxide.

The variation of a threshold voltage due to a dipole formed between the first region 16a and the second region 16b, depends on the number of the aluminum atoms to the sum of the number of the aluminum atoms and the number of the silicon atoms in the second region 16b (Al/(Al+Si)). When the Al/(Al+Si) is small, the variation of the threshold voltage is small. When the Al/(Al+Si) is large, the variation of the threshold voltage is large.

For example, when the following expression is satisfied: Al/(Al+Si)=0.08, the threshold voltage rises in a quantity of approximately 0.1 V. When the following expression is satisfied: Al/(Al+Si)=1, the threshold voltage rises by approximately 1.2 V, as described above. The Al/(Al+Si) in the second region 16b is adjusted in the MOSFET according to the present embodiment so that the threshold voltage of the MOSFET can be optimized.

The Al/(Al+Si) is preferably 0.08 or more in terms of acquisition of an effect of the rise of the threshold voltage.

Note that, the concentration distribution of the aluminum in the second region 16b is not necessarily uniform. For example, a distribution including the concentration of the aluminum rising from the side of the first region 16a to the side of a gate electrode 18 in the second region 16b, may be preferable.

According to the present embodiment, the MOSFET having a high threshold voltage can be achieved, similarly to the first embodiment. The MOSFET having a high speed can be achieved, similarly to the first embodiment. The MOSFET having a small variation of property fluctuations, similarly to the first embodiment, can be achieved. The MOSFET that is easily processed in manufacturing, can be achieved, similarly to the first embodiment. Furthermore, the Al/(Al+Si) is adjusted in the gate insulating layer 16 so that the threshold voltage of the MOSFET can be optimized.

### Third Embodiment

A semiconductor device according to the present embodiment is different from the first embodiment in that a silicon carbide region contains 3C-SiC. The descriptions of duplicate details with respect to the first embodiment, will be omitted below.

A gate electrode 18 of the MOSFET according to the present embodiment includes the p-type silicon carbide region 18a and an n-type or a p-type silicon region 18b, similarly to the first embodiment. The silicon carbide region 18a includes the 3C-SiC.

The silicon carbide region 18a is, for example, p-type 3C-SiC containing aluminum as a p-type impurity. The silicon carbide region 18a is polycrystalline 3C-SiC.

The silicon carbide region 18a is formed by stacking a 3C-SiC film including the aluminum by, for example, a CVD method. The 3C-SiC film is stacked, for example, at a temperature of 1000 to 1200° C.

Stacking the 3C-SiC film at a temperature of 1200° C. or less can inhibit SiC except for the 3C-SiC from appearing. When an SiC film is formed at a low temperature, a 3C structure is most stable.

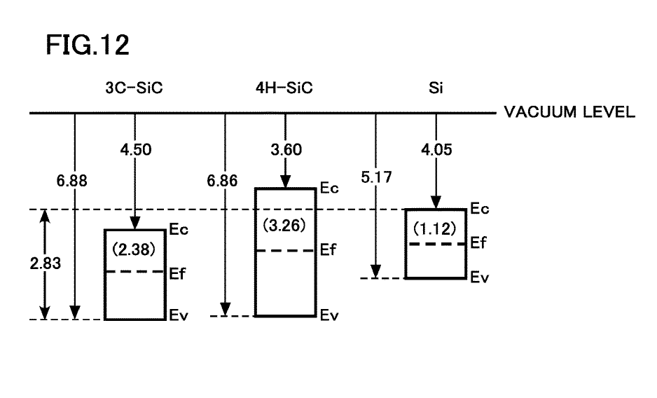

FIG. 12 is a view for describing a function and an effect of the semiconductor device according to the present embodiment. FIG. 12 illustrates a calculation result of semiconductor energy band structures by a first principles calculation.

FIG. 12 is a view of the energy band structures of silicon (Si), 4H-SiC, and 3C-SiC. The energy difference between the vacuum level and an lower end of the conduction band (Ec in the figure), the energy difference between the vacuum level and an upper end of the valence band (Ev in the figure), the band gap energy, of each of the materials, are illustrated. In the figure, a numerical value in brackets for each of the materials indicates the band gap energy.

According to the present embodiment, the p-type 3C-SiC including the aluminum is applied to the silicon carbide region 18a. As illustrated in FIG. 12, the first principles calculation clarifies that the 3C-SiC and the 4H-SiC substantially correspond to each other in terms of the energy level of the upper end of the valence band (Ev). When the p-type 3C-SiC is applied to the silicon carbide region 18a of the gate electrode 18, for example, the threshold voltage can be increased by 2.83 V in comparison to a case where n-type-silicon is applied for a gate electrode.

When an SiC gate electrode is made to contain aluminum, there is a risk that the property of a gate insulating film degrades because of high-temperature heat treatment to activate the aluminum. For example, when aluminum is introduced to the 4H-SiC so as to be activated, heat treatment is preferably performed at 1600° C. or more. When an insulating film, such as a silicon oxide film, is subjected to heat treatment at more than 1400° C., there is a risk that the property degrades.

The 3C-SiC is a crystal form which is more stable at a low temperature than the crystal form of the 4H-SiC or 6H-SiC. Crystal formation of the 3C-SiC and activation of aluminum can be made at a low temperature having a maximum temperature of 1200° C. or less.

According to the present embodiment, the 3C-SiC which can be formed at a low temperature is applied to the gate electrode 18. Accordingly, the property of a gate insulating layer 16 is inhibited from degrading in forming the gate electrode 18. Therefore, the MOSFET with reliability improved can be achieved.

All SiC present in the silicon carbide region 18a is preferably, substantially the 3C-SiC. For example, when a diffraction peak resulting from a crystal face of a crystal form except the 3C-SiC is a noise level or less, it is determined that no crystal form except for 3C-SiC is substantially present.

The volume ratio of the 3C-SiC which is occupied in the SiC and is present in the silicon carbide region 18a, is preferably 90% or more. Counting the occupying area of crystal grains being the 3C-SiC in an image acquired with a transmission electron microscope (TEM) can determine whether the volume ratio of the 3C-SiC occupying is 90° or more.

It is preferable that the volume of the 3C-SiC occupied in the SiC which is present in the silicon carbide region 18a is larger than the volume of 4H-SiC occupied in the SiC which is present in the silicon carbide region 18a. For example, counting the occupying area of the crystal grains being the 3C-SiC and the occupying area of crystal grains being the 4H-SiC in an image acquired with the TEM, can determine whether the volume occupied by the 3C-SiC is larger than volume occupied by the 4H-SiC.

It is preferable that the volume ratio of the 3C-SiC occupied in the SiC which is present in the silicon carbide region 18a is preferably 90% or more. Furthermore, all the SiC present in the gate electrode 18 is preferably, substantially the 3C-SiC. When another crystal form, such as the 4H-SiC, is mixed together, there is a risk that the resistance of the gate electrode 18 increases. The reason of the increase of the resistance may be because the resistance of a boundary between the different crystal forms becomes high.

The concentration of the p-type impurity in the silicon carbide region 18a is preferably 1×10¹⁹ cm⁻³ or more, more preferably, 1×10²⁰ cm⁻³ or more, in terms of metallization of the 3C-SiC in the silicon carbide region 18a. The concentration is further preferably 1×10²¹ cm⁻³.

According to the present embodiment, the MOSFET having a high threshold voltage is achieved, similarly to the first embodiment. The MOSFET having a high speed is achieved, similarly to the first embodiment. The MOSFET having a small variation of property fluctuations, similarly to the first embodiment, is achieved. The MOSFET that is easily processed in manufacturing, is achieved, similarly to the first embodiment. Furthermore, the temperature of heat treatment after formation of the gate insulating layer 16, is reduced so that the MOSFET with reliability improved can be achieved.

### Fourth Embodiment

A semiconductor device according to the present embodiment is different from that according to the first embodiment in that an oxide layer including an oxide of at least one element selected from the group consisting of barium (Ba), strontium (Sr), lanthanum (La), and yttrium (Y), is further provided between a silicon carbide layer and a gate insulating layer. The descriptions of duplicate details with respect to the first embodiment, will be omitted below.

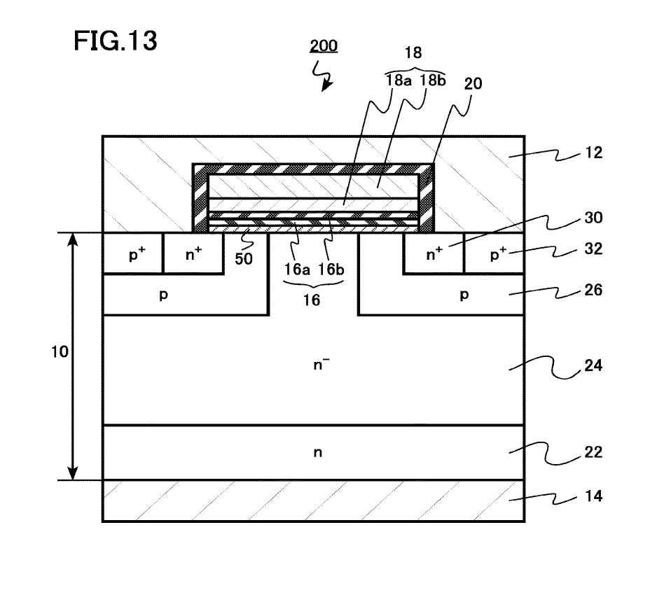

FIG. 13 is a schematic cross-sectional view of the semiconductor device according to the present embodiment. The MOSFET 200 is a DIMOSFET. The MOSFET 200 is an n-type MOSFET in which an electron serves as a carrier.

The MOSFET 200 includes the oxide layer 50 between the SiC layer (the silicon carbide layer) 10 and the gate insulating layer 16. The oxide layer 50 includes the oxide of the at least one element selected from the group consisting of the barium, the strontium, the lanthanum, and the yttrium. A case where the oxide layer 50 is a barium oxide film, will be exemplarily described below.

A case where a first region 16a is a silicon oxide film and a second region 16b is an aluminum oxide film, in the gate insulating layer 16, will be exemplarily described below.

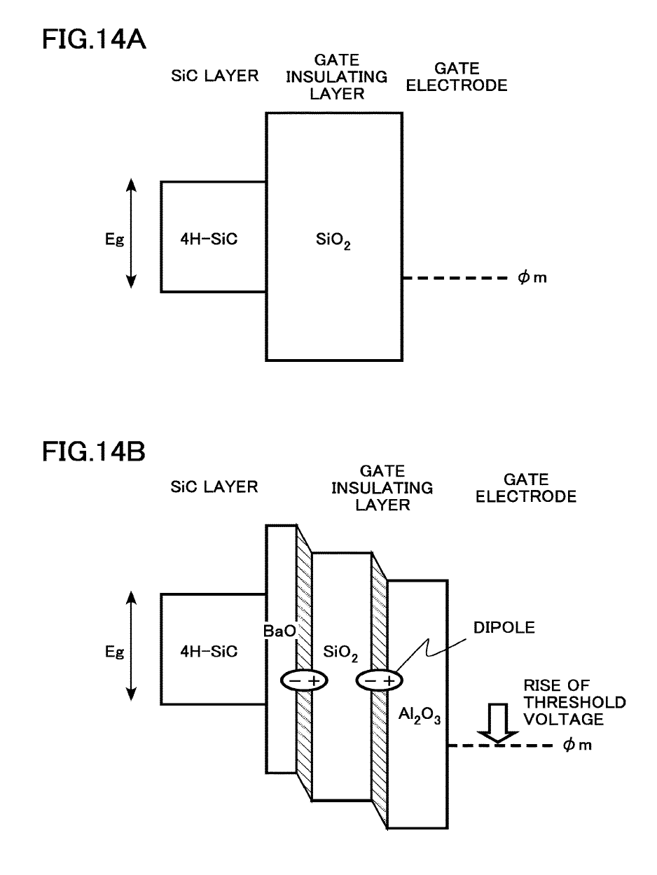

FIGS. 14A and 14B are views each for describing a function and an effect of the semiconductor device according to the present embodiment. FIGS. 14A and 14B are views each illustrating the bands of an SiC layer, agate insulating layer, and a gate electrode.

FIG. 14A illustrates a case where the gate insulating layer is a single film including a silicon oxide (SiO₂ in the figure) film. FIG. 14B illustrates a case where the gate insulating layer is a stacked film of a silicon oxide film and an aluminum oxide, and a barium oxide film is provided between the SiC layer and the gate insulating layer (BaO in the figure), similarly to the present embodiment.

As illustrated in FIG. 14B, when the silicon oxide film and the aluminum oxide film are in contact with each other, a dipole is formed therebetween. The dipole that has been formed includes a negative charge on the side of the silicon oxide film and a positive charge on the side of the aluminum oxide film.

As illustrated in FIG. 14B, when the barium oxide film and the silicon oxide film are in contact with each other, a dipole is formed therebetween. The dipole that has been formed includes a negative charge on the side of the barium oxide film and a positive charge on the side of the silicon oxide film.

As illustrated in FIG. 14B, due to the function of the two dipoles that have been formed, the work function of the gate electrode (φm in the figure) apparently increases larger than that in the case where the gate insulating layer is the single film including the silicon oxide film. Specifically, the work function increases by approximately 1.2 eV due to the dipole between the silicon oxide film and the aluminum oxide film, and increases by approximately 0.4 eV due to the dipole between the barium oxide film and the silicon oxide film.

Therefore, for example, the threshold voltage of the MOSFET 200 increases by approximately 1.6 V (1.2 V+0.4 V) higher than that in the case where the gate insulating layer is the single film including the silicon oxide film. For example, the threshold voltage increases by approximately 4.41 V (=2.81 V+1.2 V+0.4 V) higher than that in a case where the gate insulating layer is the single film including the silicon oxide film and the gate electrode is n-type silicon.

Note that, when the oxide layer 50 includes an oxide of the strontium, the lanthanum, or the yttrium, instead of the barium, a dipole is formed and the threshold voltage of the MOSFET 200 increases, similarly.

According to the present embodiment, the MOSFET 200 having a high threshold voltage is achieved, similarly to the first embodiment. The MOSFET 200 having a high speed is achieved, similarly to the first embodiment. The MOSFET 200 having a small variation of property fluctuations is achieved, similarly to the first embodiment. The MOSFET 200 that is easily processed in manufacturing, is achieved, similarly to the first embodiment. Furthermore, the oxide layer 50 is provided so that the MOSFET 200 having a further high threshold voltage is achieved.

### Fifth Embodiment

A semiconductor device according to the present embodiment is a MOSFET having a trench structure, differently from the first embodiment. The descriptions of duplicate details with respect to the first embodiment, will be omitted.

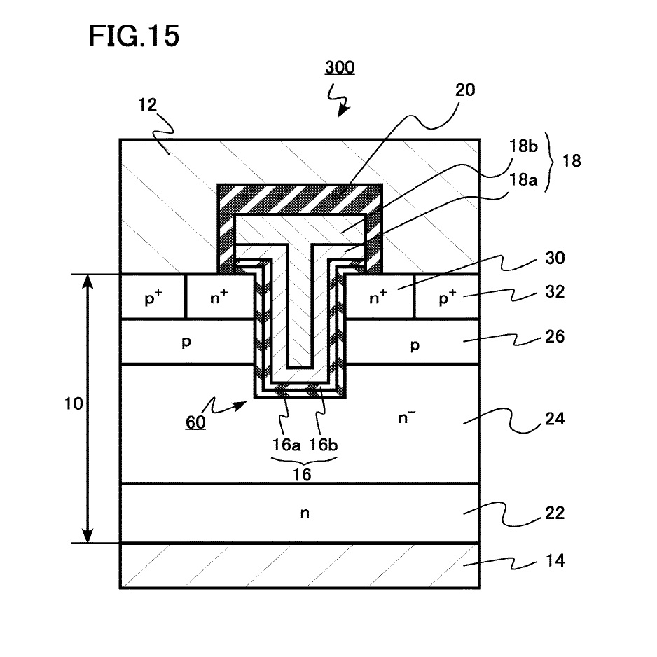

FIG. 15 is a schematic cross-sectional view of the semiconductor device according to the present embodiment. The MOSFET 300 includes the trench gate structure having a gate electrode provided in a trench.

The MOSFET 300 includes an SiC layer 10, a source electrode 12, a drain electrode 14, agate insulating layer 16, the gate electrode 18, and an interlayer insulating film 20. The SiC layer 10 includes a drain region 22, a drift region 24, a well region 26, a source region 30, and a well contact region 32.

The gate insulating layer 16 and the gate electrode 18 are formed in the trench 60 provided in the SiC layer 10.

According to the present embodiment, the MOSFET 300 having a high threshold voltage is achieved, similarly to the first embodiment. The MOSFET 300 having a high speed is achieved, similarly to the first embodiment. The MOSFET 300 having a small variation of property fluctuations, similarly to the first embodiment. The MOSFET 300 that is easily processed in manufacturing, is achieved, similarly to the first embodiment. Furthermore, providing the trench gate structure achieves the MOSFET 300 having large on-state current.

### Sixth Embodiment

A semiconductor device according to the present embodiment is an insulated gate bipolar transistor (IGBT), differently from that according to the first embodiment. The descriptions of duplicate details with respect to the first embodiment, will be omitted.

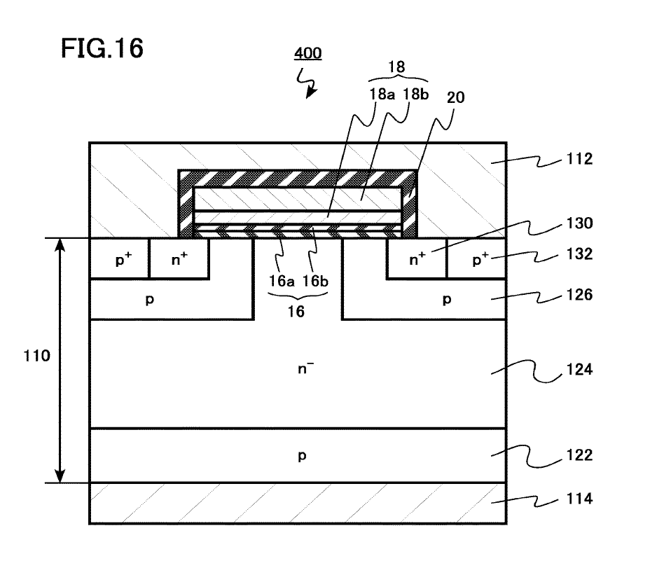

FIG. 16 is a schematic cross-sectional view of the semiconductor device according to the present embodiment.

The IGBT 400 includes an SiC layer 110, an emitter electrode 112, a collector electrode 114, a gate insulating layer 16, a gate electrode 18, and an interlayer insulating film 20. The SiC layer 110 includes a collector region 122, a drift region 124, a base region 126, an emitter region 130, and a base contact region 132.

The SiC layer 110 is, for example, 4H-SiC.

The SiC layer 110 has a first plane and a second plane. In FIG. 15, the first plane is a plane on the upper side in the figure, and the second plane is a plane on the lower side in the figure. The first plane and the second plane are referred to as a front face and a back face, respectively, below.

A case where the first plane slants at an angle of 0 to 8 degrees to a (0001) face and the second plane slants at an angle of 0 to 8 degrees to a (000-1) face, will be exemplarily described. The (0001) face is referred to as a silicon face. The (000-1) face is referred to as a carbon face.

The collector region 122 is p-type SiC. The collector region 122 includes, for example, aluminum (Al) as a p-type impurity. The concentration of the p-type impurity in the collector region 122 is, for example, between 1×10¹⁸ cm⁻³ and 1×10²¹ cm⁻³ inclusive.

In order to reduce contact resistance between the collector electrode 114 and the collector region 122, the concentration of the p-type impurity in the second plane of the collector region 122 is preferably 1×10¹⁹ cm⁻³ or more, and more preferably, 1×10²⁰ cm⁻³ or more.

The drift region 124 is provided on the collector region 122. The drift region 124 is, for example, n⁻-type SiC formed on the collector region 122 by epitaxial growth. The thickness of the drift region 124 is, for example, between 5 μm and 150 μm inclusive.

The drift region 124 includes, for example, nitrogen (N) as an n-type impurity. The concentration of the n-type impurity in the drift region 124 is, for example, between 5×10¹⁵ cm⁻³ and 2×10¹⁶ cm⁻³ inclusive.

The base region 126 is provided on the drift region 124. The base region 126 is p-type SiC. The base region 126 functions as a channel region of the IGBT 400.

The base region 126 includes, for example, aluminum (Al) as a p-type impurity. The concentration of the p-type impurity in the base region 126 is, for example, between 5×10¹⁵ and 1×10¹⁸ cm⁻³ inclusive. The depth of the base region 126 is, for example, between 0.4 μm and 0.8 μm.

The emitter region 130 is provided in the base region 126. The emitter region 130 is n′-type SiC. The emitter region 130 includes, for example, nitrogen (N) as an n-type impurity. The concentration of the n-type impurity in the emitter region 130 is, for example, between 1×10¹⁸ cm⁻³ and 1×10²¹ cm⁻³ inclusive.

In order to reduce contact resistance between the emitter electrode 112 and the emitter region 130, the concentration of the n-type impurity in the first plane of the emitter region 130 is preferably 1×10¹⁰ cm⁻³ or more, and more preferably, 1×10²⁰ cm⁻³ or more.

The depth of the emitter region 130 is shallower than the depth of the base region 126, and is, for example, between 0.2 μm and 0.4 μm inclusive.

The base contact region 132 is provided in the base region 126. The base contact region 132 is provided in a lateral direction of the emitter region 130.

The base contact region 132 is p⁺-type SiC. The base contact region 132 includes, for example, aluminum (Al) as a p-type impurity. The concentration of the p-type impurity in the base contact region 132 is, for example, between 1×10¹⁸ cm⁻³ and 1×10²¹ cm⁻³ inclusive.

The depth of the base contact region 132 is shallower than the depth of the base region 126, and is, for example, between 0.2 μm and 0.4 μm inclusive.

The gate insulating layer 16 is provided between the SiC layer 110 and the gate electrode 18. The gate insulating layer 16 is formed on the emitter region 130, the base region 126, and the drift region 124. The gate insulating layer 16 is provided between the emitter region 130, the base region 126, the drift region 124, and the gate electrode 18.

The thickness of the gate insulating layer 16 is, for example, between 50 nm and 100 nm inclusive.

The gate insulating layer 16 has a first region 16a and a second region 16b. The first region 16a is provided on the SiC layer 110 in contact with the SiC layer 110. The second region 16b is provided between the first region 16a and the gate electrode 18. The second region 16b is in contact with the gate electrode 18.

The gate electrode 18 is provided on the gate insulating layer 16. The gate electrode 18 includes a p-type silicon carbide region 18a and an n-type or a p-type silicon region 18b. The silicon carbide region 18a is interposed between the gate insulating layer 16 and the silicon region 18b.

The interlayer insulating film 20 is provided on the gate electrode 18. The interlayer insulating film 20 is, for example, a silicon oxide film.

The base region 126 interposed between the emitter region 130 and the drift region 124 below the gate electrode 18, functions as a channel region of the IGBT 400.

The emitter electrode 112 is provided on the front face of the SiC layer 110. The emitter electrode 112 is electrically connected to the emitter region 130 and the base contact region 132. The emitter electrode 112 also has a function of applying potential to the base region 126.

The emitter electrode 112 is metal. The metal that forms the emitter electrode 112 has a stacked structure of titanium (Ti) and aluminum (Al). The metal that forms the emitter electrode 112 may react with the SiC layer 110 so as to form metal silicide or metal carbide.

The collector electrode 114 is provided on the back face of the SiC layer 110. The collector electrode 114 is electrically connected to the collector region 122.

The collector electrode 114 is metal. The metal that forms the collector electrode 114 is, for example, a titanium-aluminum alloy.

According to the present embodiment, the IGBT 400 having a high threshold voltage is achieved due to a function similar to that according to the first embodiment. The IGBT 400 having a high speed is achieved, similarly to the first embodiment. The IGBT 400 having a small variation of property fluctuations is achieved, similarly to the first embodiment. The IGBT 400 that is easily processed in manufacturing, is achieved, similarly to the first embodiment.

### Seventh Embodiment

A driving device having an inverter circuit according to the present embodiment, includes the semiconductor device according to the first embodiment.

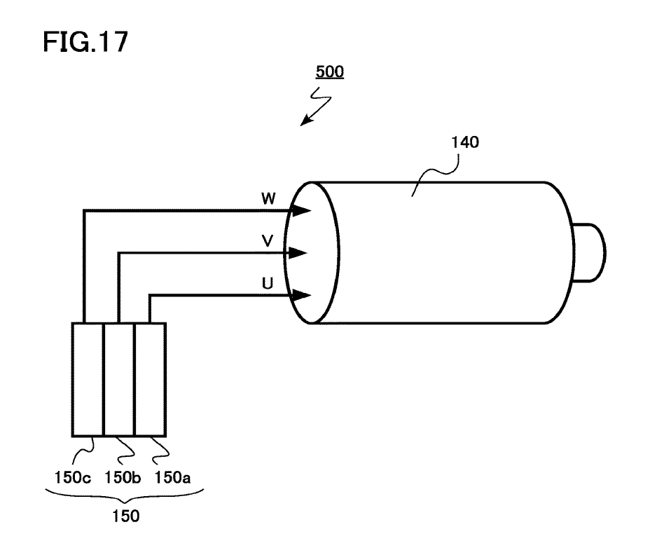

FIG. 17 is a schematic view of the driving device according to the present embodiment. The driving device 500 includes a motor 140 and the inverter circuit 150.

The inverter circuit 150 includes three semiconductor modules 150a, 150b, and 150c each having the MOSFET 100 according to the first embodiment as a switching element. The three semiconductor modules 150a, 150b, and 150c are coupled in parallel so that the three-phase inverter circuit 150 having three output terminals U, V, and W for alternating-current voltage, is achieved. The motor 140 is driven with the alternating-current voltage output from the inverter circuit 150.

According to the present embodiment, the MOSFETs 100 each having a property improved are provided so that the properties of the inverter circuit 150 and the driving device 500 improve.

### Eighth Embodiment

A vehicle according to the present embodiment includes the semiconductor device according to the first embodiment.

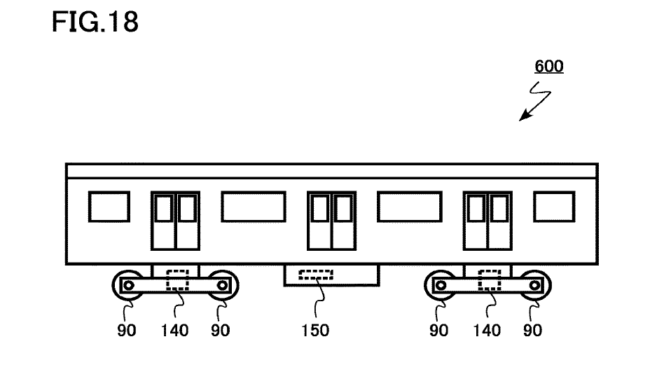

FIG. 18 is a schematic view of the vehicle according to the present embodiment. The vehicle 600 according to the present embodiment is a railway vehicle. The vehicle 600 includes a motor 140 and an inverter circuit 150.

The inverter circuit 150 includes three semiconductor modules each having the MOSFET 100 according to the first embodiment as a switching element. The three semiconductor modules are coupled in parallel so that the three-phase inverter circuit 150 having three output terminals U, V, and W for alternating-current voltage, is achieved. The motor 140 is driven with the alternating-current voltage output from the inverter circuit 150. The motor 140 rotates wheels 90 of the vehicle 600.

According to the present embodiment, the MOSFETs 100 each having a property improved are provided so that the property of the vehicle 600 improves.

### Ninth Embodiment

A vehicle according to the present embodiment includes the semiconductor device according to the first embodiment.

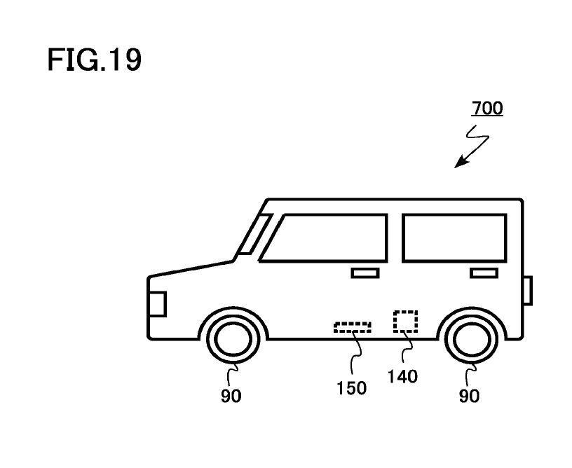

FIG. 19 is a schematic view of the vehicle according to the present embodiment. The vehicle 700 according to the present embodiment is a motor vehicle. The vehicle 700 includes a motor 140 and an inverter circuit 150.

The inverter circuit 150 includes three semiconductor modules each having the MOSFET 100 according to the first embodiment as a switching element. The three semiconductor modules are coupled in parallel so that the three-phase inverter circuit 150 having three output terminals U, V, and W for alternating-current voltage, is achieved.

The motor 140 is driven with the alternating-current voltage output from the inverter circuit 150. The motor 140 rotates wheels 90 of the vehicle 700.

According to the present embodiment, the MOSFETs 100 having a property improved are provided so that the property of the vehicle 700 improves.

### Tenth Embodiment

An elevator according to the present embodiment includes the semiconductor device according to the present embodiment.

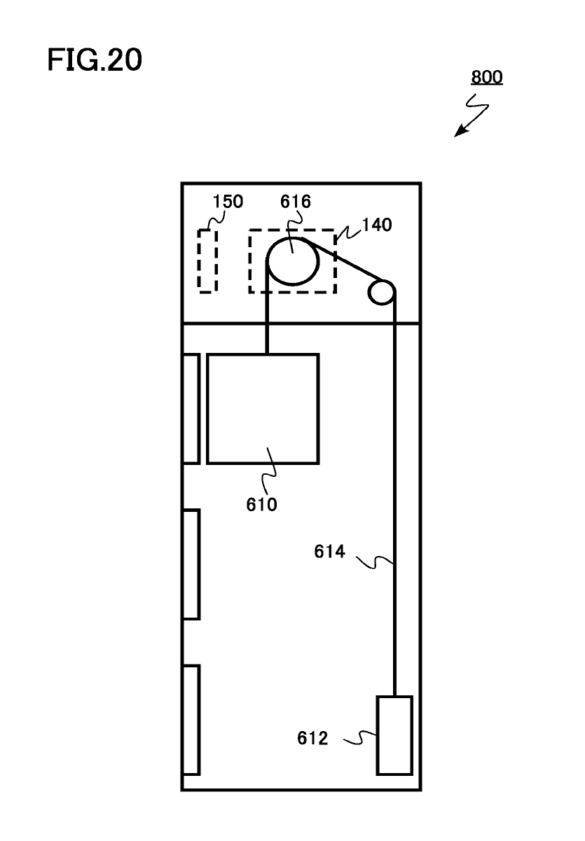

FIG. 20 is a schematic view of the elevator according to the present embodiment. The elevator 800 according to the present embodiment includes a cage 610, a counterweight 612, a wire rope 614, a hoist 616, a motor 140, and an inverter circuit 150.

The inverter circuit 150 includes three semiconductor modules each having the MOSFET 100 according to the first embodiment as a switching element. The three semiconductor modules are coupled in parallel so that the three-phase inverter circuit 150 having three output terminals U, V, and W for alternating-current voltage, is achieved.

The motor 140 is driven with the alternating-current voltage output from the inverter circuit 150. The motor 140 rotates the hoist 616 so that the cage 610 rises and falls.

According to the present embodiment, the MOSFETs 100 each having a property improved are provided so that the property of the elevator 800 improves.

According to the third embodiment, a method of forming the 3C-SiC by the CVD method has been exemplified for the formation of the silicon carbide region 18a of the gate electrode 18. The silicon carbide region 18a can be also formed by sputtering with a target of SiC including aluminum, and crystallization annealing at 1200° C. or less. The silicon carbide region 18a can be also formed by ion implantation of aluminum to the 3C-SiC stacked by the CVD method, and activation annealing at 1200° C. or less.

According to the first to sixth embodiments, a case where the SiC layer is the 4H-SiC has been exemplified, but another crystal form, such as 3C-SiC or 6H-SiC, can be used. In terms of the achievement of the device having a high breakdown voltage, the 4H-SiC having large band gap energy is preferably applied as the SiC layer. In terms of the increase of the threshold voltage, the 4H-SiC having the large band gap energy is preferably applied as the SiC layer.

According to the first to sixth embodiments, the nitrogen (N) has been exemplified as the n-type impurity of the SiC, but phosphorus (P), arsenic (As), or antimony (Sb), can be applied instead of the nitrogen (N).

According to the eighth to tenth embodiments, a case where the semiconductor device according to present disclosure is applied to the vehicles and the elevator, has been exemplarily described. The semiconductor device according to the present disclosure can be applied to, for example, a power conditioner in a photovoltaic system.

While certain embodiments have been described, these embodiments have been presented by way of example only, and are not intended to limit the scope of the inventions. Indeed, a semiconductor device, an inverter circuit, a driving device, a vehicle, and an elevator described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
a silicon carbide layer;
a gate electrode including a p-type silicon carbide region containing aluminum; and
a gate insulating layer positioned between the silicon carbide layer and the gate electrode, the gate insulating layer having a first region and a second region, the first region including a silicon oxide or a silicon oxynitride, the second region being positioned between the first region and the gate electrode, the second region including an oxide containing aluminum.

2. The semiconductor device according to claim 1,
wherein the concentration of the aluminum in the silicon carbide region is 1×10¹⁹ cm⁻³ or more.

3. The semiconductor device according to claim 1,
wherein the thickness of the silicon carbide region is between 10 nm and 30 nm inclusive.

4. The semiconductor device according to claim 1,
wherein the second region contains silicon, and
the number of aluminum atoms to the sum of the number of the aluminum atoms and the number of silicon atoms, is 0.08 or more.

5. The semiconductor device according to claim 1,
wherein the gate electrode includes an n-type or a p-type silicon region, the silicon carbide region being interposed between the n-type or the p-type silicon region and the gate insulating layer, the n-type or the p-type silicon region having a thickness thicker than the thickness of the silicon carbide region.

6. The semiconductor device according to claim 1,
wherein the silicon carbide region includes 3C-SiC.

7. The semiconductor device according to claim 6,
wherein the volume of the 3C-SiC in the silicon carbide region is larger than the volume of 4H-SiC in the silicon carbide region.

8. The semiconductor device according to claim 1, further comprising:
an oxide layer positioned between the silicon carbide layer and the gate insulating layer, the oxide layer including an oxide of at least one element selected from the group consisting of barium, strontium, lanthanum, and yttrium.

9. The semiconductor device according to claim 1,
wherein the silicon carbide layer is 4H-SiC.

10. The semiconductor device according to claim 1,
wherein the silicon carbide layer is p-type, the silicon carbide layer containing aluminum.

11. An inverter circuit comprising:
the semiconductor device according to claim 1.

12. A driving device comprising:
the semiconductor device according to claim 1.

13. A vehicle comprising:
the semiconductor device according to claim 1.

14. An elevator comprising:
the semiconductor device according to claim 1.
